(19) United States
(12) Patent Application Publication
(10) Pub. No.: US 2003/0062126 A1
(43) Pub. Date: Apr. 3, 2003

(54) Method and apparatus for assisting laser material processing

(76) Inventor: Michael J. Scaggs, Weston, FL (US)

Correspondence Address: SMITH & HOPEN PA, 15950 BAY VISTA DRIVE, SUITE 220, CLEARWATER, FL, 33760

(21) Appl. No.: 10/065,262

(22) Filed: Sep. 30, 2002

Related U.S. Application Data
(60) Provisional application No. 60/327,413, filed on Oct. 3, 2001.
(60) Provisional application No. 60/328,737, filed on Oct. 10, 2001.

(51) Int. Cl. C23C 14/00; C23F 1/00

(52) U.S. Cl. 156/345.26; 118/712; 156/345.5; 118/50.1

(57) ABSTRACT

A laser machining apparatus includes a nozzle connected to a pressurized gas and liquid reservoir for propelling a fine spray, mist or stream of a liquid such as water at the workpiece to be machined. A laser beam, preferably as may be generated by a UV laser or other source of exposure radiation, but is not strongly absorbed by the liquid assist material, is focused to the workpiece using, e.g., a focusing or imaging lens, while the fine spray, mist or liquid stream is propelled at the workpiece creating a layer of the liquid on its surface as the beam is incident upon the workpiece for machining.

### CROSS REFERENCE TO RELATED APPLICATIONS

This application claims the benefit of Provisional Application Ser. No. 60/327,413 filed Oct. 3, 2001 and Provisional Application Ser. No. 60/328,737 filed Oct. 10, 2001.

### BACKGROUND OF THE INVENTION

Excimer lasers have been considered poor choices as exposure radiation sources for machining metals due to the generation of severe recast and debris during the laser interaction. High repetition rate, Q-switched YAG lasers also generate a recast and debris field when machining metals. These YAG lasers may be focused to a small spot and rastered over the area to be cut so that the generation of recast and debris may be somewhat tempered. However, the generation of recast and debris using a YAG laser in this way will still not be eliminated or even suppressed below a sufficient tolerance level.

Laser etching of materials submersed in liquid baths has been performed and is described at U.S. Pat. No. 5,057,184, which is hereby incorporated by reference. In the '184 patent, the part or workpiece being etched is submersed in a liquid bath and the fluence of the laser source is kept at a relatively low level, e.g., 2.1 J/cm². The exposure source lasers described in the '184 patent, i.e., copper vapor, YAG and chopped CW argon ion lasers, each emit in the visible region above 400 nm. The '184 patent teaches to avoid higher fluences as recast and cracks will form.

A method may be used wherein a large, perhaps unregulated amount of liquid is flowed over a sample. However, particularly at laser repetition rates such as greater than a few Hz and particularly at repetition rates above 1 kHz, such use of thick liquid flow layers, e.g., greater than 1 mm, results in high turbulence and reduced performance through refraction affects of the liquid. Still other methods may use a slow spiral trepanning for holes or multipass cuts to increase the width of the kerf.

Unfortunately, this adds time to the process and generally does not eliminate the recast and debris altogether.

It is desired to have an apparatus and method for laser machining of workpieces such as metal substrates that does not produce an intolerable level of recast and debris.

### SUMMARY OF INVENTION

In view of the above, a method and apparatus for assisting laser material processing is provided, particularly for machining workpiece materials such as metal, semiconductor substrates, ceramic, glass and polymers. The apparatus includes a nozzle for propelling a fine spray, mist or continuous stream of a liquid such as water at the workpiece to be machined. A laser beam, preferably as may be generated by a UV laser or other source of exposure radiation generated between 190 nm and 1100 (for water), and is not strongly absorbed by the liquid assist, is focused or imaged onto the workpiece using, e.g., a focusing or imaging lens, while the spray, mist or liquid stream is propelled at the workpiece creating a layer of the liquid on the workpiece surface as the beam is incident upon the workpiece to machine the workpiece.

Preferably, the liquid is propelled using a propellant such as pressurized nitrogen, helium, argon or any other non-absorbing gas for the wavelength being used or by means of a liquid pump and a liquid reservoir. The liquid is propelled by the pressurized gas or liquid through a spray or jet nozzle to the workpiece. The liquid nozzle may have an orifice between 15000 microns, such as around 300 microns, and the pressure of the liquid at the nozzle may be several psi, such as between 5100 psi, and specifically may be around 18 psi. Further, the orifice may be shaped with an elongated profile having a 1 to 5000 micron dimension in one axis and 1 micron to 100 mm dimension in the other axis. Having an elongated nozzle profile provides the means to cover a larger area. In some laser systems an opto-galvanic system directs the laser beam onto a workpiece. In an opto-galvanic system, the laser beam is vector scanned over the workpiece and can cover a field of 100 mm×100 mm or more. In this scenario a nozzle that covers a small area for a “fixed” laser beam would be in adequate for the task. Also preferably, a wet suction hose is provided for drawing the liquid from the surface of the workpiece. Alternatively, the liquid is simply allowed to run-off the workpiece and/or may be collected as it runs-off, filtered and reused.

Preferably, the flowing water layer is less then 100 microns thick, and may be as thin as can be maintained as a continuous sheet of liquid over the application region, and the flowing liquid layer may be within a range between 25-100 microns, and more specifically between 25-50 microns. The area covered may be between a few square millimeters to 100 square centimeters and depends on the geometry of the applied laser beam. The flow rate may be around one milliliter per minute or greater, again depending upon the laser beam geometry and the scan field of a galvanometer system.

A method includes generating a laser beam preferably at a wavelength less than 1100 nm and directing and/or focusing the beam to a workpiece for exposing and machining the workpiece, and propelling a liquid, and preferably a non-absorbing liquid such as water, at the workpiece for creating a thin layer of the liquid on the surface of the workpiece to be processed by the laser beam. The propelling operation is preferably begun prior to or coincident with the exposing of the workpiece with the laser beam. A wet vacuum operation is preferably also performed while the liquid is being propelled to the workpiece.

In the form of an apparatus, the present invention includes a work platform for holding a workpiece upon which a laser beam is applied. A fluid conduit is adapted to discharge fluid across the surface of the workpiece and a flow control means is fluidly coupled to the fluid conduit, the flow control means is adapted to regulate the discharge of fluid across the workpiece concurrent with the application of the laser beam. As opposed to immersion of the workpiece in a fluid container, an embodiment of the present invention provides a substantially constant application of fluid to the workpiece. It is preferred that the fluid discharged across the workpiece is substantially transmissive relative to light emitted from the laser beam. In an exemplary embodiment of the invention, the fluid is water and laser beam emits light at wavelengths between 190 and 1100 nm.

A propellant conduit adapted to discharge propellant may be provided wherein the propellant conduit is fluidly coupled to the fluid conduit and a nozzle is fluidly coupled to the fluid conduit whereby the fluid is discharged across the workpiece by the propellant. In a preferred embodiment, an atomizing means discharges the fluid and propellant together as a fine mist spray. Similar to the optimum absorptive properties of the fluid, it is preferred that the propellant is substantially transmissive relative to light emitted from the laser beam. The propellant is preferably an inert gas including, but not limited to, air, nitrogen, helium, argon, carbon dioxide or the like.

A fluid vacuum adapted to withdraw fluid discharged across the workpiece may be provided to remove excess fluid and keep the thickness of the fluid over the workpiece optimized. It is anticipated that the flow control means, nozzle, fluid vacuum and other mechanical elements of the present invention be computer controlled as is known in the art wherein predefined procedures and optimizations in the process may be reproduced consistently.

In an embodiment of the invention, a computer processor is communicatively coupled to the flow control means and a computer readable medium is communicatively coupled to the computer processor. A fluid control module stored on the computer readable medium is adapted to stop the discharge of fluid across the workpiece prior to completing a cut-through of the workpiece by the laser beam. In a preferred embodiment, the computer processor is communicatively coupled to both the flow control means and the propellant conduit and the fluid control module stored on the computer readable medium is adapted to stop the discharge of fluid across the workpiece by closing off the fluid conduit means and removing residual fluid from the workpiece by opening the propellant conduit prior to completing a cut-through of the workpiece by the laser beam to push residual fluid off the workpiece.

In yet another embodiment of the invention, a secondary reservoir holding at least one light-reactive chemical is provided with a secondary control valve disposed between the secondary reservoir and the fluid conduit whereby activation of the secondary control valve introduces the at least one light-reactive chemical into the fluid conduit.

In another embodiment a liquid absorbing covering is placed over the workpiece upon which the laser beam is applied. The covering may be a porous material such as cellulose which holds the fluid and is relatively inert when exposed to the laser beam.

A drainage conduit may be provided coincident to the workpiece and adapted to recover excess fluid initially discharged across the workpiece. Preferably, the drainage conduit is fluidly coupled to the fluid conduit with a filter disposed there between whereby excess fluid is filtered and recirculated.

As a method, the present invention includes the steps of discharging a film of fluid across the workpiece and applying a laser beam to the workpiece. The fluid is preselected so that it is substantially transmissive relative to light emitted from the laser beam. Preferably, the preselected fluid is water and the laser beam emits light at wavelengths between 190 and 1100 nm. A propellant may be introduced into the fluid, the propellant substantially transmissive relative to light emitted from the laser beam. The propellant is an inert gas such as nitrogen, helium, argon or carbon dioxide. By vacuum means or by directing the propellant towards the workpiece, excess fluid discharged across the workpiece is removed.

In a preferred method of carrying out the invention, prior to completing a cut-through of the workpiece, the discharge of fluid across the workpiece is ceased and the residual liquid is pushed off the workpiece by propellant injection.

### BRIEF DESCRIPTION OF DRAWINGS

For a fuller understanding of the nature and objects of the invention, reference should be made to the following detailed description, taken in connection with the accompanying drawings, in which:

FIG. 1 is a schematic view of an embodiment of the invention.

FIG. 2 is a schematic view of an alternative embodiment of the invention utilizing a recirculation system.

FIG. 3 is a schematic view of an alternative embodiment of the invention for introducing a light-reactive chemical into the fluid conduit.

FIG. 4 is a schematic view of an alternative embodiment of the invention utilizing a recirculation system.

FIG. 5 is a diagrammatic view of an embodiment of the invention.

### DETAILED DESCRIPTION

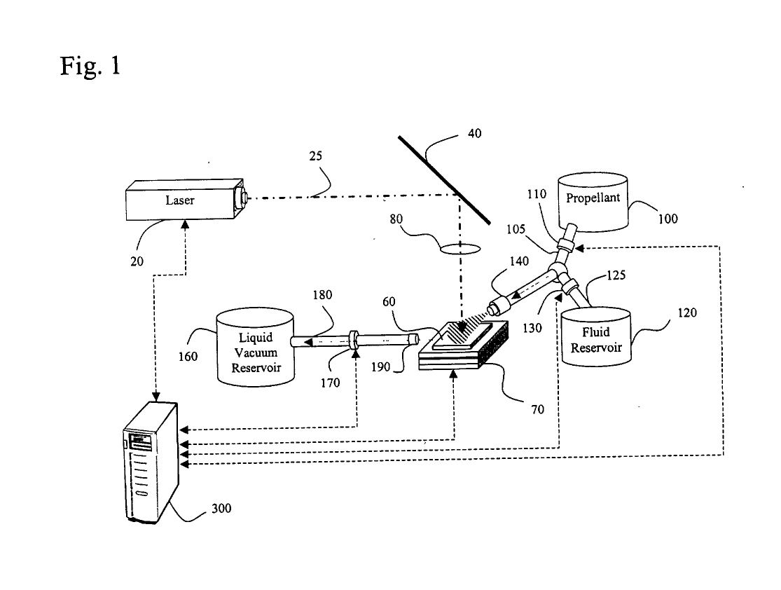

FIG. 1 generally illustrates an apparatus for assisting laser material processing according to the invention. The apparatus shown at FIG. 1 includes an exposure source 20 such as a laser for generating a beam of radiation at wavelengths less than 1100 nm, although longer wavelength radiation sources may be used and benefit from use with the preferred embodiments. It is important that the wavelength of the laser radiation is highly transmissive for the liquid being used as the assist material. In the case of far infrared sources, e.g., carbon dioxide (CO₂) lasers emitting around 10.6 microns, a liquid gas like N₂, Ar, CO₂ and the like may be used as the assist material to aid the laser machining where simple liquids like water strongly absorb the radiation. The repetition rate may be as low as a few Hz or may be operated in cw mode, although operating at higher repetition rates such as 1 kHz or more, the low thickness water layer preferred herein is particularly advantageous as producing significantly low turbulence and greatly improving the performance of the device, e.g., as compared with a device wherein a flow liquid layer has a thickness of one millimeter or more. A mirror 40 is shown for redirecting the laser beam toward a workpiece 60 such as a metal, semiconductor, ceramic, glass or polymer substrate.

The radiation is preferably focused onto the workpiece 60 by a focusing or imaging lens 80.

FIG. 1 also generally shows a device including a propellant 100, a propellant conduit 105, a propellant gas valve 110, a liquid reservoir 120, a liquid valve 130 and a fine spray nozzle 140. The fine spray nozzle 140 may be any of a variety, and an exemplary nozzle has an orifice of 300 microns and a nozzle pressure of 18 psi, although greater or smaller nozzle orifices and nozzle pressures may be used. A flow rate on the workpiece may be produced at around one milliliter per minute, although the flow rate will depend on the workpiece area and will increase if the speed of the liquid is faster for some reason perhaps depending on the configuration of the workpiece, such as may depend on how much gravity is allowed to be involved, as well as the nozzle geometry, pressure or propellant speed.

The device shown in FIG. 1is configured such that as the propellant 100, such as nitrogen gas, is propelled under pressure through the device for expulsion through the nozzle 140, liquid, such as water, alcohols, or other non laser wavelength-absorbing liquid, is expelled from the device with the propellant 100 through the fine spray, mist, or liquid nozzle to be incident on the surface of the workpiece 60 to be machined by the laser beam 25. The liquid then flows over the workpiece region to be processed. The flowing liquid layer has preferably a substantially uniform thickness of less than 100 200 microns, and particularly between 25 and 60 microns, but may be a few hundred microns depending on the liquid being used and ability to obtain uniform flow at a minimal flow layer thickness. The flowing liquid layer area may be 1-100 square centimeters, and particularly around 25 mm, and will depend on the area of the application beam. The flowing liquid may be channeled such as by provided walls around the application workspace, e.g., using 60 micron thick tape or perhaps greater if the flow layer thickness is somewhat greater than 60 microns, or shims or other material. The shaping of the flow using the channeling may be advantageous in providing improved uniformity of the flow of the non laser wavelengthabsorbing liquid.

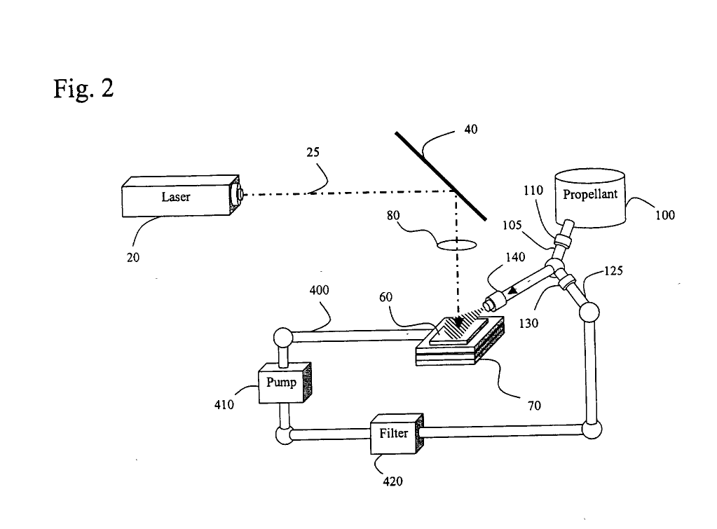

FIG. 1 further generally shows a vacuum device including a liquid vacuum reservoir 160, a vacuum valve 170 coupled to a liquid vacuum conduit 180 and nozzle 190, which includes a motor or other device for creating a suction at the nozzle 190. The nozzle 190 is disposed near the surface of the workpiece 60 for wet vacuuming the liquid from the surface of the workpiece 60 as the workpiece is machined on X-Y-Z motion stages 70 and the liquid is propelled to its surface from the fine spray, mist or continuous liquid stream nozzle 140. As shown in FIG. 2, the part or sample chuck can be designed in such a way that the liquid is allowed to drain off via a channel or series of channels that run along the outer region of the chuck. At a convenient location in the channel would be a drainage hole for which the expelled liquid could drain through a drainage conduit 400 to another reservoir or be filtered and be sent back to the liquid source reservoir for reuse. The drained or vacuumed liquid would contain the material by products that could be recycled or easily collected through filters 420 for easy recycling or waste disposal. FIG. 1 further shows that the controller 300 controls the operation of the X-Y-Z motion stages, propellant valve 110, liquid valve 130, the vacuum valve 170 and the operation of the laser 20.

In particular, the laser 20 may be a frequency tripled Nd:YAG (355 nm) or other solid state laser apparatus directly emitting or frequency-multiplied to emit an ultraviolet beam, and the laser may generate another sub −400 nm wavelength such as may be emitted by an excimer laser, in particular XeF emitting at 351 nm, XeCl emitting at 308 nm, KrF emitting at 248 nm, KrCl emitting at 222 nm and ArF emitting at 193 nm, or a VUV molecular fluorine laser emitting at 157 nm, or even an EUV generating source such as may be used to generate radiation around 11 nm to 15 nm, and generally an exposure source generating radiation at wavelengths less than 1100 nm, although even a longer wavelength exposure source may be used in an apparatus that would benefit according to the preferred embodiments herein. The preferred laser beam may be advantageously applied to an inorganic material with a fluence of more than approximately 2 J/cm². Although as mentioned, this process is not limited to use with UV lasers or exposure sources having wavelength less than 1100 nm, but is understood as working best with UV exposure light, wherein use of a 248 nm KrF excimer laser beam is specifically preferred as exhibiting high performance.

The laser light is directed onto a sample of material to be machined, such as to be cut, grooved, drilled, etched, or otherwise to machine the workpiece 60 as understood by those skilled in the art of laser machining, using the focusing or imaging lens 80 and mirror 40. Fluences on the order of >3.5 J/cm² may be used to achieve very fast etch rates and high throughput. The materials best suited for use as workpieces 60 with this technique include metals such as stainless steel, cold rolled steel, nickel, brass, copper, molybdenum, and other metals that may be machined as understood by those skilled in the art, i.e., not limited to the metals mentioned above, and semiconductors such as silicon, bismuth telluride, and other semiconductors that may be machined as understood by those skilled in the art, i.e., not limited to the semiconductor materials mentioned above, as well as some insulators made of ceramic, glass and polymers. Optimum fluences for polymers when using the assist is in the range of 100 mJ/cm to <1 J/cm². The workpiece 60 may be disposed vertically, horizontally or otherwise at any angle relative to gravity, and the laser beam is preferably normally incident at the workpiece 60, but may be somewhat offset depending on the machining application desired.

A fine spray, mist or stream of liquid or a thin liquid layer, and preferably a liquid of non laser wavelength-absorbing material such as water for wavelengths between 190 and 1100 nm, is directed to the laser interaction region of the workpiece 60 as propelled from the nozzle 140 such that a fine stream of the preferred liquid forms a flow over the laser interaction region while the workpiece 60 is being machined by the beam from the laser 20. Generally, the thinner the stream of liquid and the more laminar the flow, the better the effect of the assist, as long as the liquid layer is not so thin that there is insufficient liquid material to achieve the purposes of these preferred embodiments. For example, a few cubic centimeters of liquid in the reservoir 120 can be used for a great deal of machining according to a preferred embodiment. The stream of liquid is preferably maintained very thin during machining in order to minimize deleterious refraction effects as the beam interacts with the liquid layer before and after impinging upon the workpiece 60.

The liquid assist device including propellant 100, liquid reservoir 120 and nozzle 140, as illustrated schematically at FIG. 1, is preferably disposed in close proximity to the target workpiece 60 to create the thin stream of liquid, preferably water, that approaches as close as possible a laminar flow, wherein the less turbulent the flow of the liquid is, the better. It has been observed that if the spray nozzle 140 is disposed far from the surface of the workpiece 60, then droplets may begin to form and the laminar flow may be deteriorated. In a particular preferred embodiment, the nozzle 140 may be disposed such that the workpiece 60 is positioned at a “focal point” of the spray/jet, or a point in the flow of the liquid in the stream where cross-sectional flow uniformity may be relatively high. The advantageous use of the water assist, or other preferably non laser-wavelength-absorbing liquid assist, according to the preferred embodiment herein permits production of substantially burr free laser etched features, with minimal to no deposit of ablation particulates around the laser etched area. Further, the flow of liquid over the laser and material interaction region has the added benefit of cooling the material being laser machined; thus greatly reducing the heat-affected zone.

In laser machining materials, a continuous stream of water or other liquid can be applied. A pulsed stream of this water may be used for drilling small holes or blind features. This is advantageous because as the laser beam approaches the bottom of the material of the workpiece 6, a shock wave created at the water/laser interaction boundary may otherwise cause the material to “punch” out the back side with a resulting jagged hole. In order to avoid this effect, controller 300 opens propellant gas valve 110 followed by liquid valve 130. Vacuum suction valve 170 is opened to collect the spent liquid from the nozzle 140. Controller 300 initiates the laser 20 trigger and the movement of the X-Y-Z motion stages 70. At a pointjust before where the liquid assist might causes break out or chipping of the substrate 60, as result of high pressures generated in the laser interaction region, the controller 300 closes the liquid valve 130. At this point the propellant gas 100 pushes the residual liquid from the laser interaction area so that no chipping or breakage will occur from shock waves generated from the laser and liquid interaction.

By using the water or other liquid assist in accordance with the preferred embodiment, substantially recast free features may be achieved, with very little, if any, debris. Moreover, the recast generated in an unassisted cut tends to block the radiation from penetrating deeper into the material, or the recast material may re-melt and adhere to the bulk material being cut. The laser material processing with water or other liquid assist according to the preferred embodiment provides a clean (debris free), burr free and fast cut without disadvantageous recasts and/or re-melts interfering with the processing and/or use of the processed workpiece 60.

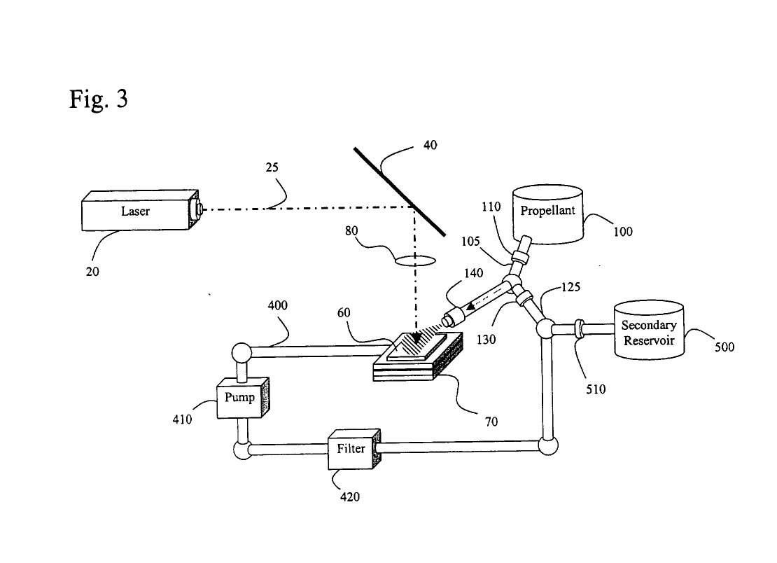

A further benefit of the liquid assist process is that chemical componds may be added to the liquid such that the chemical compounds react to the laser radiation and or with the material being treated as shown in FIG. 3. Secondary reservoir 500 holding This laser/chemical compound reaction can result in surface chemistry that could alter the material being processed in order to increase surface wettability, surface texture, add impurities, dopents to name a few. The surface chemistry would only occur where the laser beam meets the liquid assist containing the chemical compound. The wavelength and fluence of the laser would be selected based upon the chemistry required and the fluence would likely be at or below the ablation threshold of the material being treated.

The preferred embodiment may be used in many industrial applications. For example, it can be used to engrave printing plates, etch and cut medical devices such as stents or catheters and microelectronic probes, create MEMS structures in metals and semiconductors like silicon. In non-metals, such as semiconductors, ceramics, glass and polymer insulators, it can aid in eliminating debris generated in the ablation process and therefore eliminate or reduce the time, cost and effort otherwise typically involved in a post-cleaning process. Using the liquid assist technique in polymer machining has shown not only an improvement in in the reduction of debris, but also a significant improvement in the optical resolution through the reduction of the heat-affected zone. This technique facilitates the creation of optical waveguide devices in polymers coated onto semiconductor or glass substrates or in the creation of any optical MEMS device formed from a polymer. It was experimentally found with the preferred embodiment that when the propellant gas used was helium, the performance of machining polymers was further enhanced. In one case the lens being used had an imaging resolution of 3 microns. The KrF excimer laser etched <2 micron wide lines through 7 micron thick polymer waveguide material deposited onto silicon. The collateral residue of the removed polymer was noticeably less than with nitrogen gas used as the propellant gas for the liquid. Post processing of flexible circuits and microelectronic circuits of any type, for example, can be eliminated after they are processed by laser assisted liquid etching. The debris is washed away and no oxides remain on underlying metalization. This would further apply towards the clean removal of insulation around conductive wires or fiber optics. Contact lens or interoccular lens device cutting or trimming of flashing would equally benefit from this technique. Advantageously, the apparatus and method of the preferred embodiment have been shown to permit machining at up to at least 20 mm per minute, as compared with past techniques that have permitted only around 8 mm per minute machining using a 3 watt, 355 nm Nd:YAG laser in cutting 670 micron thick silicon. Consequently, the cutting or dicing of silicon or sapphire wafers can be accomplished with minimal kerf width and little to no slag or debris on the periphery of the cuts and with fastest possible speeds. In addition, the past techniques typically have involved a clean-up process, whereas little or no clean-up may be performed in accord with the preferred embodiment.

Many different types of nozzles 140 or spray devices may be used to apply the liquid mist, fine spray or liquid stream to the workpiece 60. Even a continuous flow of liquid from a hose, faucet or other orifice landing on the sample may be advantageous. As the stream of water hits the sample it spreads relatively uniformly over the interaction region of the workpiece 60 and can form a thin sheet of water. As long as the stream of water does not have air bubbles, or create much turbulence when it hits the sample, it may be advantageously used in accordance with alternative embodiments herein to produce the desired conditions.

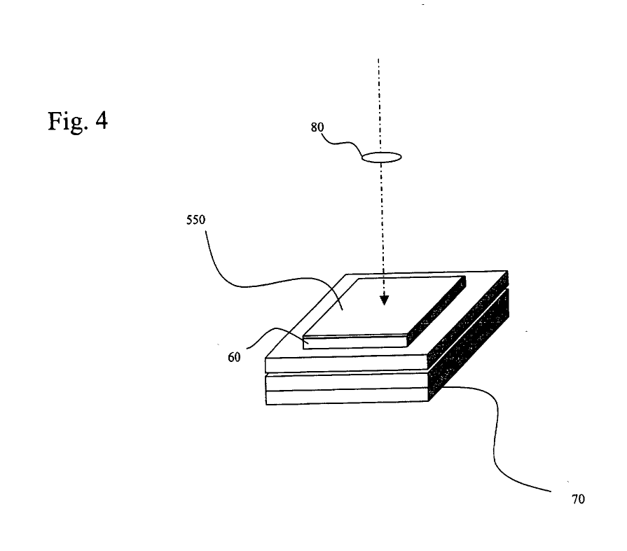

Another alternative method may be used which involves the use of some kind of “wicking” device as shown in FIG. 4. A piece of tissue or other thin material 550 may be placed over the workpiece 60 and then soaked with liquid. The laser 20 would cut through the thin, liquid absorbing material 550 and begin cutting the subject workpiece 60. The thin and saturated absorbing material 550 would supply a continuous source of liquid to the desired area. This alternative embodiment may have the disadvantage of not producing optimal liquid flow, and in fact the flow of liquid may be quite minimal according to this embodiment, but it would have a positive advantageous effect over past systems and techniques.

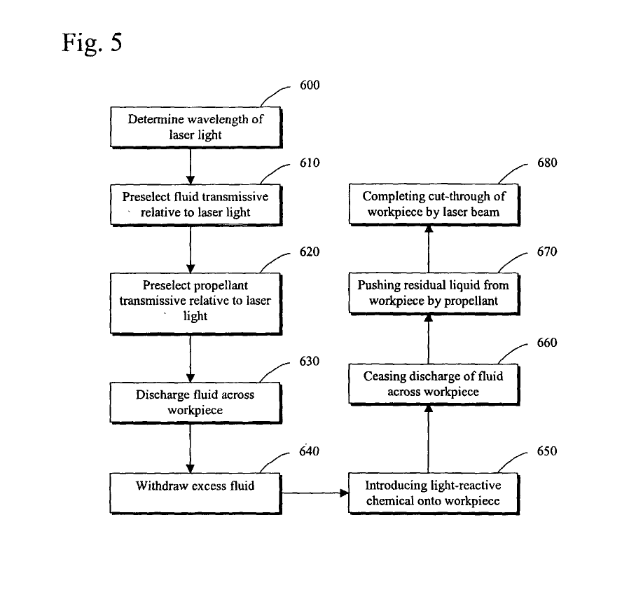

In FIG. 5, the wavelength of the laser light is first determined 600. Depending on the wavelength a fluid is preselected 610 which is transmissive at the wavelength of the laser light. Preferably, the preselected fluid is water and the laser beam emits light at wavelengths between 190 and 1100 nm. Similarly, a propellant is preselected 620 which is also transmissive at the wavelength of the laser light. The propellant is an inert gas such as nitrogen, helium, argon or carbon dioxide. The fluid is discharged 630 across the workpiece and by vacuum means or by directing the propellant towards the workpiece, excess fluid discharged across the workpiece is withdrawn 640. A light-reactive chemical may be introduced 650 onto the workpiece along with the fluid. In a preferred method of carrying out the invention, prior to completing a cut-through of the workpiece 680, the discharge of fluid across the workpiece is ceased 660 and the residual liquid is pushed off the workpiece by propellant injection 670.

While an exemplary drawing and specific embodiments of the present invention have been described and illustrated, it is to be understood that that the scope of the present invention is not to be limited to the particular embodiments discussed. Thus, the embodiments shall be regarded as illustrative rather than restrictive, and it should be understood that variations may be made in those embodiments by workers skilled in the arts without departing from the scope of the present invention.

In addition, in methods that may be performed according to preferred embodiments herein and that may have been described above, the operations have been described in selected typographical sequences. However, the sequences have been selected and so ordered for typographical convenience and are not intended to imply any particular order for performing the operations. For example, although it is preferred to begin the flow of the liquid across the surface of the workpiece before beginning the machining with the laser beam, the flow of liquid may be started after the machining is started, and the vacuuming may be started before or after either of the liquid flow or machining started.

It will be seen that the objects set forth above, and those made apparent from the foregoing description, are efficiently attained and since certain changes may be made in the above construction without departing from the scope of the invention, it is intended that all matters contained in the foregoing description or shown in the accompanying drawings shall be interpreted as illustrative and not in a limiting sense.

It is also to be understood that the following claims are intended to cover all of the generic and specific features of the invention herein described, and all statements of the scope of the invention which, as a matter of language, might be said to fall there between. Now that the invention has been described,

1. An apparatus for laser material processing comprising:
a work platform for holding a workpiece upon which a laser beam is applied;
a fluid conduit adapted to discharge fluid across the surface of the workpiece; and
a flow control means fluidly coupled to the fluid conduit, the flow control means adapted to regulate the discharge of fluid across the workpiece concurrent with the application of the laser beam.

2. The apparatus of claim 1 wherein the fluid discharged across the workpiece is substantially transmissive relative to light emitted from the laser beam.

3. The apparatus of claim 2 wherein the fluid is water and laser beam emits light at wavelengths between 190 and 1100 nm.

4. The apparatus of claim 1 further comprising:
a propellant conduit adapted to discharge propellant, the propellant conduit fluidly coupled to the fluid conduit; and
a nozzle fluidly coupled to the fluid conduit whereby the fluid is discharged across the workpiece by the propellant.

5. The apparatus of claim 4 further comprising an atomizing means for discharging the fluid and propellant together as a spray.

6. The apparatus of claim 4 wherein the propellant is substantially transmissive relative to light emitted from the laser beam.

7. The apparatus of claim 6 wherein the propellant is nitrogen.

8. The apparatus of claim 6 wherein the propellant is helium.

9. The apparatus of claim 6 wherein the propellant is argon.

10. The apparatus of claim 6 wherein the propellant is carbon dioxide.

11. The apparatus of claim 1 further comprising a fluid vacuum adapted to withdraw fluid discharged across the workpiece.

12. The apparatus of claim 1 further comprising a computer processor communicatively coupled to the flow control means.

13. The apparatus of claim 4 further comprising a computer processor communicatively coupled to the nozzle.

14. The apparatus of claim 11 further comprising a computer processor communicatively coupled to the fluid vacuum.

15. The apparatus of claim 1 further comprising:
a computer processor communicatively coupled to the flow control means;
a computer readable medium communicatively coupled to the computer processor;
a fluid control module stored on the computer readable medium adapted to stop the discharge of fluid across the workpiece prior to completing a cut-through of the workpiece by the laser beam.

16. The apparatus of claim 4 further comprising:
a computer processor communicatively coupled to the flow control means and the propellant conduit;
a computer readable medium communicatively coupled to the computer processor;
a fluid control module stored on the computer readable medium adapted to stop the discharge of fluid across the workpiece by closing off the fluid conduit means and removing residual fluid from the workpiece by opening the propellant conduit prior to completing a cut-through of the workpiece by the laser beam to push residual fluid off the workpiece.

17. The apparatus of claim 1 further comprising:
a secondary reservoir holding at least one light-reactive chemical;
a secondary control valve disposed between the secondary reservoir and the fluid conduit whereby activation of the secondary control valve introduces the at least one light-reactive chemical into the fluid conduit.

18. The apparatus of claim 1 further comprising a drainage conduit coincident to the workpiece and adapted to recover excess fluid initially discharged across the workpiece.

19. The apparatus of claim 18 wherein the drainage conduit is fluidly coupled to the fluid conduit whereby excess fluid is recirculated.

20. The apparatus of claim 19 further comprising a filter disposed in fluid communication between the drainage conduit and fluid conduit.

21. An apparatus for laser material processing comprising:
a work platform for holding an workpiece upon which a laser beam is applied; and
a liquid absorbing covering placed over the workpiece, the covering adapted to be cut through by the laser beam.

22. A laser material processing method comprising the steps of:
discharging a film of fluid over a workpiece and applying a laser beam to the workpiece.

23. The method of claim 22 further comprising the step of preselecting a fluid that is substantially transmissive relative to light emitted from the laser beam.

24. The method of claim 23 wherein the preselected fluid is water and the laser beam emits light at wavelengths between 190 and 1100 nm.

25. The method of claim 22 further comprising the step of introducing a propellant into the fluid.

26. The method of claim 25 further comprising the step of preselecting a propellant that is substantially transmissive relative to light emitted from the laser beam.

27. The method of claim 25 wherein the propellant is nitrogen.

28. The method of claim 25 wherein the propellant is helium.

29. The method of claim 25 wherein the propellant is argon.

30. The method of claim 25 wherein the propellant is carbon dioxide.

31. The method of claim 22 further comprising the step of withdrawing excess fluid discharged across the workpiece.

32. The method of claim 22 further comprising the step of providing a computer processor adapted to control the discharge of fluid across the workpiece.

33. The method of claim 31 further comprising the step of providing a computer processor adapted to control the withdraw of excess fluid from the workpiece.

34. The method of claim 22 further comprising the step of ceasing the discharge of fluid across the workpiece prior to the laser beam completing a cut-through of the workpiece.

35. The method of claim 34 further comprising the step of pushing residual liquid from the workpiece by propellant injection prior to the laser beam completing a cut-through of the workpiece.

36. The method of claim 22 further comprising the step of introducing at least one light-reactive chemical onto the workpiece.
